(19) United States
(12) Patent Application Publication
(10) Pub. No.: US 2018/0122966 A1
(43) Pub. Date: May 3, 2018

(54) SOLAR CELL MODULE

(71) Applicant: Kaneka Corporation, Osaka (JP)

(72) Inventors: Kunta Yoshikawa, Osaka (JP); Hayato Kawasaki, Osaka (JP); Kunihiro Nakano, Osaka (JP); Toru Terashita, Osaka (JP)

(73) Assignee: Kaneka Corporation, Osaka (JP)

(21) Appl. No.: 15/856,877

(22) Filed: Dec. 28, 2017

Related U.S. Application Data
(63) Continuation of application No. PCT/JP2016/069359, filed on Jun. 29, 2016.

(30) Foreign Application Priority Data
Jun. 30, 2015 (JP) 2015-131637

(51) Int. Cl. H01L 31/0224; H01L 31/0465; H01L 31/048; H01L 31/18

(52) U.S. Cl. CPC H01L 31/022425; H01L 31/0465; H01L 31/02013; H01L 31/1884; H01L 31/048

(57) ABSTRACT

A solar cell module includes a first solar cell including, in the following order, a single-crystalline silicon substrate, a conductive silicon layer, and a back side transparent electrode layer, where the conductive silicon layer and the back side transparent electrode layer are disposed on a back side of the single-crystalline silicon substrate; an encapsulant; and a flexible metal foil disposed between the back side transparent electrode layer and the encapsulant. The flexible metal foil is in contact with the back side transparent electrode layer in a non-bonded state. The encapsulant encapsulates the first solar cell and maintains a contact state between the flexible metal foil and the back side transparent electrode layer.

### TECHNICAL FIELD

The present invention relates to a solar cell module including a crystalline silicon solar cell.

### BACKGROUND ART

Crystalline silicon solar cells produced using a crystalline silicon substrate have high photoelectric conversion efficiency, and have already been widely put into practical use as solar photovoltaic power generation systems. A crystalline silicon solar cell in which a silicon-based thin-film having a gap different from that of single-crystalline silicon is disposed on a surface of a single-crystalline silicon substrate to form a semiconductor junction is called a heterojunction solar cell, and exhibits particularly conversion efficiency among crystalline silicon solar cells.

In the crystalline silicon solar cell, carriers generated in a crystalline silicon are collected by a metal electrode disposed on the light-receiving side and the back side. The heterojunction solar cell includes a transparent electrode layer such as a transparent conductive oxide (TCO) between a silicon-based thin-film and a metal electrode. Carriers collected by the metal electrode are extracted to outside through a strip-shaped interconnector connected to the metal electrode.

Patent Document 1 discloses that when a metal plate or metal foil having high rigidity onto a patterned metal electrode (Ag paste electrode) or a transparent electrode layer on the back side of a solar cell with a conductive adhesive interposed therebetween, damage by an external force during transportation, stress in an encapsulation process or the like can be suppressed. Patent Document 2 discloses that when an interconnector is connected to the back side of a solar cell, and the entire back surface is covered with a conductive sheet, series resistance can be reduced, and the thickness of the interconnector can be reduced, so that warpage and breakage of the solar cell can be suppressed.

### PRIOR ART DOCUMENT

### Patent Documents

Patent Document 1: Japanese Patent Laid-open Publication No. 2007-201331
Patent Document 2: Japanese Patent Laid-open Publication No. 2005-167158

### SUMMARY OF THE INVENTION

### Problems to be Solved by the Invention

When a rigid member or a metallic member such as an interconnector is mounted on a light-receiving surface and a back surface of a crystalline silicon solar cell with a conductive adhesive etc. interposed therebetween, stress is generated at a bonding interface by heating in modularization, a temperature change in practical use, or the like due to, for example, a difference in thermal linear expansion coefficient between crystalline silicon and the metallic member. In a module structure as in Patent Document 1 and Patent Document 2, a metallic member is bonded and mounted on each of both a light-receiving surface and a back surface of a solar cell, and therefore there is a difference between the magnitudes and directions of stress at the bonding interface on the front side and on the back side, so that warpage and breakage due to strain of the cell, peeling of the metallic member, and so on easily occur. There is also the problem that use of a conductive adhesive causes an increase in production cost.

An object of the present invention is to provide a solar cell module in which deterioration of properties, cell breakage, peeling of an interconnector and so on due to a temperature change hardly occur, so that excellent reliability is exhibited.

### Means for Solving the Problems

A solar cell module according to the present invention includes a solar cell in which a conductive silicon layer and a back side transparent electrode layer are disposed in this order on the back side of a single-crystalline silicon substrate; an encapsulant; and a flexible metal foil disposed between the solar cell and the encapsulant. The metal foil is in contact with the back side transparent electrode layer of the solar cell in a non-bonded state. The solar cell is encapsulated by the encapsulant, and thus a contact state between the metal foil and the back side transparent electrode layer is retained.

Preferably, at least a part of the metal foil which is in contact with the back side transparent electrode layer includes at least one selected from the group consisting of Sn, Ag, Ni, In, and Cu. The thickness of the metal foil is preferably 4 to 190 μm.

Preferably, the metal foil is provided with a plurality of openings, and the encapsulant is in contact with the solar cell through the openings. The diameter of the opening provided in the metal foil is preferably 100 μm to 2000 μm, and the distance between openings closest to each other is preferably 5 mm to 100 mm.

On the back side transparent electrode layer of the solar cell, a plurality of dot-shaped buffer electrodes may exist separately from one another. On a surface of the solar cell on the back side, the area of a region occupied by the buffer electrodes is preferably less than 1% of the area of a region in which the back side transparent electrode layer is exposed. When dot-shaped buffer electrodes are disposed on the back surface of the solar cell, it is preferable that the metal foil is in contact with the back side transparent electrode layer and the buffer electrodes in a non-bonded state, and is electrically connected to the back side transparent electrode layer and the buffer electrodes.

When the solar cell includes a patterned metal electrode on the light-receiving surface, back electrodes and light-receiving side metal electrodes in two adjacent solar cells are electrically connected to perform interconnection. In two adjacent solar cells, a metal foil that is in contact with a back side transparent electrode in one solar cell (“first solar cell”) and a metal electrode on a light-receiving surface of the other solar cell (“second cell”) are mounted to a connection member to electrically connect the two adjacent solar cells.

Solar cells may be interconnected using a wiring sheet with a metal foil fixed on an insulating member. When the metal foil is provided with a plurality of openings, it is preferable that the insulating member has opening sections at positions corresponding to the openings of the metal foil. In this embodiment, it is preferable that the encapsulant is in contact with the solar cell through the opening sections provided in the insulating member and the openings provided in the metal foil. The diameter of the opening section of the insulating member is preferably smaller than the diameter of the opening provided in the metal foil.

### Effects of the Invention

In a solar cell module according to the present invention, interconnection is performed through a metal foil that is in contact with the back side of a solar cell in a non-bonded state, and therefore even when a temperature change occurs, stress strain is hardly generated, so that excellent temperature reliability is exhibited. The use amount of the metal electrode material on the back side is reduced, resulting in contribution to cost reduction.

### BRIEF DESCRIPTION OF THE DRAWINGS

FIG. 1 is a schematic view showing one embodiment of a solar cell module.

FIG. 2 is a schematic view showing one embodiment of a solar cell.

FIG. 3A is a plan view showing one examples of a pattern of the light-receiving side metal electrode.

FIG. 3B is a plan view showing one examples of a pattern of the light-receiving side metal electrode.

FIG. 4 is a conceptual view showing a state in which a metal foil is in contact with a back surface of a solar cell in a non-bonded state.

FIG. 5 is a plan view of a solar cell having buffer electrodes.

FIG. 6 shows a cross-section of a solar cell module including a solar cell having buffer electrodes.

FIG. 7 is a sectional view of a solar cell module including a metal foil provided with openings.

FIG. 8A is a plan view of a light-receiving surface of a solar cell module.

FIG. 8B is a plan view of a back surface of a solar cell module.

FIG. 9 is a conceptual view illustrating a state in which light is captured from a back surface of a solar cell.

FIG. 10A is a plan view of a wiring sheet to be used for interconnection of solar cells.

FIG. 10B is a sectional view of a wiring sheet to be used for interconnection of solar cells.

FIG. 11 is a sectional view showing a state in which solar cells are disposed on a wiring sheet.

FIG. 12A is a plan view of solar cell strings connected by a wiring sheet.

FIG. 12B is a plan view of solar cell strings connected by a wiring sheet.

FIG. 13 is a schematic view showing one embodiment of a solar cell module.

### DESCRIPTION OF EMBODIMENTS

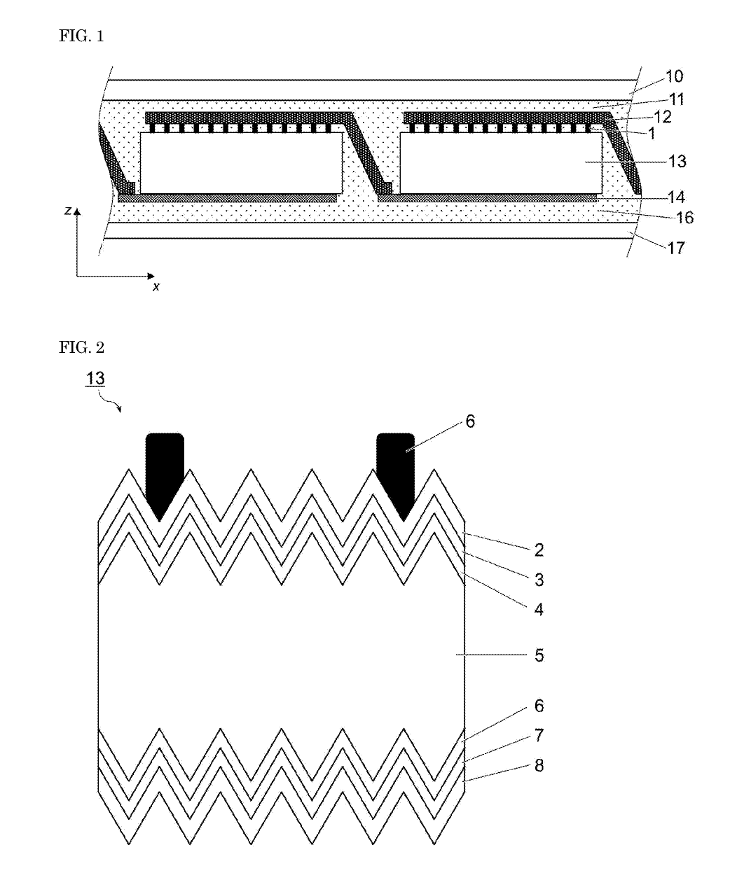

FIG. 1 is a schematic view showing a solar cell module structure according to one embodiment of the present invention. A solar cell module (hereinafter, sometimes referred to as a “module”) has a configuration in which a solar cell (hereinafter, sometimes referred to as a “cell”) is encapsulated by an encapsulant. The module shown in FIG. 1 includes a light-receiving surface protecting member 10, a light-receiving side encapsulant 11, a connection member 12, a cell 13, a metal foil 14, a back side encapsulant 16 and a back sheet 17 in this order from the light-receiving side.

For encapsulants 11 and 16, a resin such as EVA (ethylene vinyl acetate) or a polyolefin is used. The resin is heated and melted, and fluidized, so that the encapsulant flows between adjacent cells and to edges of the module to perform modularization.

The light-receiving surface protecting member 10 disposed on the light-receiving side of a cell include is light-transmissive, and examples of the material thereof include glass substrates (blue glass substrates and white glass substrates), and organic films such as fluororesin films such as polyvinyl fluoride films (e.g., TEDLAR FILM (registered trademark)), and polyethylene terephthalate (PET) films. From the viewpoint of mechanical strength, light transmittance, moisture resistance reliability, costs and so on, white glass substrates are especially preferable.

The back sheet 17 disposed on the back side of the cell may have any of light-transmissivity, light-absorbency and light-reflectivity. As the back sheet having light-transmissivity, one described above as a material of the light-receiving surface protecting material is preferably used. As the back sheet having light-reflectivity, one having a metallic color or white color is preferable, and a white resin film, a laminate with a metal foil of aluminum etc. sandwiched between resin films, or the like is preferably used. As the back sheet having light-absorbency, for example, one including a black resin layer is used.

On the back side of the cell 13, the metal foil 14 is disposed between the cell 13 and the back side encapsulant 16. The metal foil 14 is in contact with the back surface of the cell 13 in a non-bonded state, and is thus electrically connected to the cell. Before modularization, the cell 13 and the metal foil 14 are in detachable contact with each other. In the module, the cell is encapsulated by the encapsulant to retain a contact state between the metal foil and the cell.

FIG. 2 shows a schematic view of a cross-section of a crystalline silicon solar cell. A crystalline silicon solar cell 13 includes a back side conductive silicon layer 7 and a back side transparent electrode layer 8 on the back side of a single-crystalline silicon substrate 5. Preferably, a back side intrinsic silicon layer 6 is provided between the single-crystalline silicon substrate 5 and back side conductive silicon layer 7.

Preferably, a light-receiving side intrinsic silicon layer 4, a light-receiving side conductive silicon layer 3 and a light-receiving side transparent electrode layer 2 are formed on the light-receiving side of the single-crystalline silicon substrate 5. The light-receiving side conductive silicon layer 3 has a conductivity-type opposite to that of the back side conductive silicon layer 7. Thus, one of the light-receiving side conductive silicon layer 3 and the back side conductive silicon layer 7 is p-type, and the other is n-type. The conductivity-type of the single-crystalline silicon substrate 5 may be either p-type or n-type. It is preferable to use an n-type single-crystalline silicon substrate from the viewpoint of a lifetime.

Preferably, fine irregularity (texture) structures having a height of about 2 to 10 μm are formed on a surface of the single-crystalline silicon substrate 5. Pyramidal irregularity structure whose surfaces are composed of (111) plane can be formed on the single-crystalline silicon substrate by anisotropic etching. Preferably, irregularity structures are formed on both the light-receiving surface and the back surface of the solar cell.

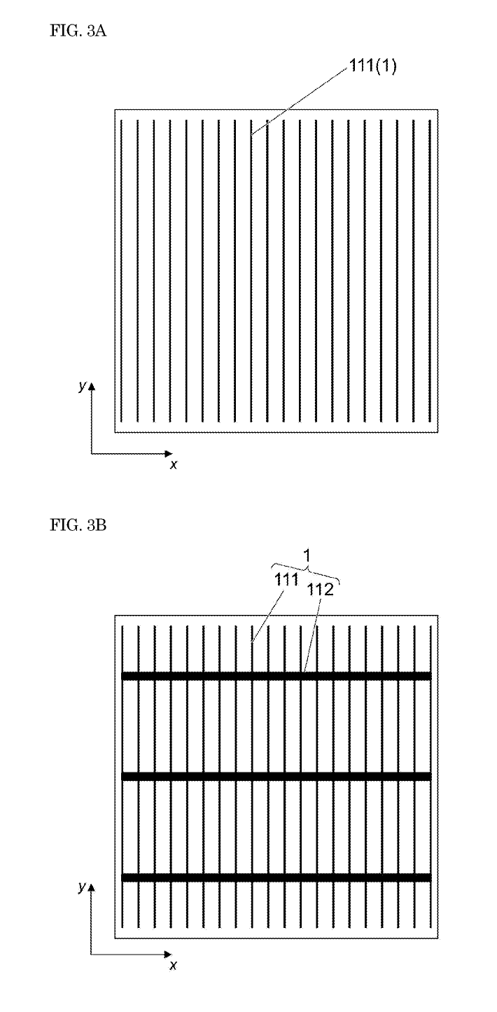

In the solar cell shown in FIG. 2, a metal electrode is not disposed on the back side transparent electrode layer 8. On the light-receiving side transparent electrode layer 2, a patterned metal electrode is disposed as a light-receiving side electrode 1. The light-receiving side metal electrode 1 acts to transport a current in the in-plane direction of the light-receiving surface of the cell 13, and therefore the light-receiving side metal electrode 1 has a two-dimensional pattern in the in-plane direction of the light-receiving surface. Examples of the two-dimensional pattern in the in-plane direction include a shape in which a plurality of finger electrodes 111 extending in parallel as shown in FIG. 3A, and a grid shape pattern including finger electrodes 111 and bus bar electrodes 112 orthogonal to the finger electrodes as shown in FIG. 3B. When the light-receiving side metal electrode 1 includes only finger electrodes as shown in FIG. 3A, a connection member is disposed so as to extend across a plurality of finger electrodes in the module. When a grid shape light-receiving side metal electrode having bus bar electrode as shown in FIG. 3B is provided, a connection member is disposed on the bus bar electrode 112.

The flexible metal foil 14 is disposed on the back surface of the cell 13. In the module, the metal foil 14 and the back side transparent electrode layer 8 of the cell are in contact with each other in a non-bonded state. In this specification, the state in which the metal foil and the back side transparent electrode layer (and the buffer electrode) are “contact . . . in a non-bonded state” means a state in which the metal foil and the back side transparent electrode layer are brought into contact with each other by applying a physical external force such as pressing or suction. Accordingly, in the state before encapsulation is performed using the encapsulant, the metal foil and the cell are in detachable contact with each other. A state in which the metal foil and the back side transparent electrode are bonded to each other by an adhesive, a molten solder or the like, and a state in which a metal electrode is formed on the transparent electrode layer by printing, plating, sputtering or the like do not correspond to the “contact . . . in a non-bonded state”

The metal foil 14 may be partially fixed on the back surface of the cell with a conductive adhesive material such as a conductive film, solder or conductive paste or an insulating adhesive material such as a pressure sensitive adhesive tape interposed therebetween. The partial fixation is temporary tacking for fixing the positional relationship between the cell 13 and the metal foil 14, and is not intended to adhesively stack the cell 13 and the metal foil 14 together. Thus, when the metal foil is partially fixed on the back surface of the cell, the metal foil and the cell are in contact with each other in a non-bonded state at portions other than temporary stacking portions. When the metal foil is partially fixed on the back surface of the cell, there may be one temporary stacking portion. For suppressing such a failure that the metal foil is turned up during operation such as encapsulation, it is preferable to perform temporary stacking at two or more portions. As described in detail later, a metal foil may be fixed on an insulating support base material. In this case, temporary tacking of the cell to the metal foil is unnecessary, so that operability in modularization can be improved.

As a material of the metal foil 14, one having low contact resistance with the back side transparent electrode layer, or a sort metal is preferably used. The metal having low contact resistance is preferably Ag, Ni, Au or the like, and the sort metal is preferably Sn, Cu, In, Al or the like. The metal foil 14 may be a single layer, or may have a plurality of stacked metal layers. When the metal foil is a single layer, it is preferable to use a metal foil including at least one metal selected from the group consisting of Sn, Ag, Ni, In, and Cu. In particular, it is preferable to use a copper foil as the metal foil 14 because it has a high reflectance and is inexpensive. For the metal foil in which a plurality of metal layers are stacked, it is preferable that a metal layer including at least one selected from the group consisting of Sn, Ag, Ni, In, and Cu is used for the contact surface with the back side transparent electrode layer. For example, a metal foil in which a low-contact resistance metal layer of Ag or the like as a contact layer with the back side transparent electrode layer is provided on a copper foil surface may be used.

The thickness of the metal foil 14 is preferably 4 to 190 μm, more preferably 10 to 100 μm, especially preferably 15 to 50 μm. When the thickness of the metal foil is 4 μm or more, an increase in electric resistance of the metal foil itself can be suppressed. When the thickness is 190 μm or less, a local increase in resistance can be suppressed because the metal foil has flexibility, and can follow the surface shape of the cell. By using a metal foil including a material as described above and having a thickness within the above-mentioned range, uniform contact with the back side transparent electrode layer, and moderate strength and flexibility of the metal foil can be secured.

In the module in FIG. 1, a space between the light-receiving surface protecting member 10 and the back sheet 17 is filled with encapsulants 11 and 16. By performing encapsulation with the metal foil 14 disposed on the back surface of the cell 13, a contact state between the back side transparent electrode layer and the metal foil is retained. By fixing the metal foil by an external force from the encapsulant, the metal foil and the back side transparent electrode layer can be brought into uniform contact with each other. Since the cell and the metal foil are in a non-bonded state, stress at the interface is relaxed. Thus, deterioration of properties due to cell breakage and strain is suppressed, so that a module having high reliability is obtained.

In a state in which the metal foil and the transparent electrode are in contact with each other, void portions may exist on a part of the surface of the back side between the metal foil and the transparent electrode. FIG. 4 is an enlarged view of the back side of a module in which the metal foil 14 is in contact, in a non-bonded state, with the top of the back side transparent electrode layer 8 of the cell 13 having irregularities on the back surface of a silicon substrate.

When irregularity structures are formed on the back side of the cell, peak portions (projections) of the irregularity structures come into contact with the metal foil to establish electrical contact. When the back side transparent electrode layer on the peaks of irregularity structures and periphery thereof are brought into contact with the metal foil, it is preferable that the irregularity size is small, and the number of peaks per area (pea density) is large.

When the back surface of the cell has irregularity structures, a region surrounded by the back side transparent electrode layer 8 and the metal foil 14 is not filled with an encapsulant, and thus forms a void. The void portion 18 is filled with a gas (air) before encapsulation, and is in a state close to vacuum after encapsulation. After encapsulation, the void portion 18 is in a negative pressure state, and therefore a contact state between the metal foil 14 and the back side transparent electrode layer 8 is retained.

Single-crystalline silicon has a small light absorption coefficient for near infrared light, and therefore, of light incident to the cell from the light-receiving surface, most of light having a long wavelength of 950 nm or more reaches the back side without being absorbed in the single-crystalline silicon substrate. Since the refractive index of a metal oxide material that forms the transparent electrode layer is about 2 while the refractive index of the void portion is about 1 to 1.05, a part of light reaching the back surface of the cell is reflected at the interface between the back side transparent electrode layer and the void, and is incident to the silicon substrate again. Remained part of the light reaching the back surface of the cell passes through the interface between the back side transparent electrode layer, and is then reflected at the interface between the void and the metal film, passes through the interface between the back side transparent electrode layer and the void again, and is incident to the cell again.

Preferably, a void portion exists between the transparent electrode and the metal foil in a region occupying 80% or more and less than 100% of the projected area of a surface of the back side transparent electrode. In particular, for securing conductivity with the metal foil while securing a maximum reflectance on the back side, it is preferable that a void portion exists in a region occupying 85% or more and less than 100% of the projected area of the surface of the back side transparent electrode, and it is especially preferable that a void portion exists in a region occupying 90% or more and less than 100% of the projected area of the surface of the back side transparent electrode.

The “surface of back side transparent electrode” means a region in which the back side transparent electrode is exposed in a state before it is brought into contact with the metal foil. Thus, it is preferable that the void portion occupies 80% or more and less than 100% of the region, and the other region, i.e., a region occupying more than 0% and 20% or less of the aforementioned region, is in contact with the metal foil. When metal electrodes such as dot-shaped buffer electrodes are provided on the back side transparent electrode as described later, a region which is not provided with the metal electrodes corresponds to the “surface of back side transparent electrode”.

As one of the effects of this embodiment, plasmon absorption at the interface between the back side transparent electrode and the metal electrode does not occur because the metal electrode is not formed directly on the back side transparent electrode.

Generally, in a heterojunction solar cell, the thickness of the back side transparent electrode layer is set to 80 to 100 nm to maximize reflection at the interface between silicon and the back side transparent electrode layer for reducing plasmon absorption at the interface between the back side transparent electrode layer and the metal electrode. On the other hand, when a metal foil as the back side metal electrode is brought into physical contact with the back side, plasmon absorption at the interface between the back side transparent electrode layer and the metal electrode can be suppressed to considerably reduce the thickness of the back side transparent electrode layer to about 20 nm. By reducing the thickness of the back side transparent electrode layer, absorption of light by the back side transparent electrode layer is reduced, and therefore light utilization efficiency can be further improved.

When the thickness of the back side transparent electrode layer is small, mechanical damage to the peaks of irregularities tends to easily occur. Dot-shaped buffer electrodes 9 may be provided on the back side transparent electrode layer 8 for suppressing mechanical damage to the cell. FIG. 5 is an enlarged view of the back surface of the cell provided with dot-shaped buffer electrodes. As described above, the light-receiving side metal electrode 1 is two-dimensionally provided while extending in at least one direction in the plane, whereas buffer electrodes 9 provided on the back surface is not required to have a function of transporting a current in the in-plane direction of the back surface. Thus, as shown in FIG. 5, a plurality of buffer electrodes 9 exist separately from one another. When the metal foil 14 comes into contact with the back side transparent electrode layer 8 and the buffer electrode 9, the back side transparent electrode layer is electrically connected to a plurality of buffer electrodes through the metal foil.

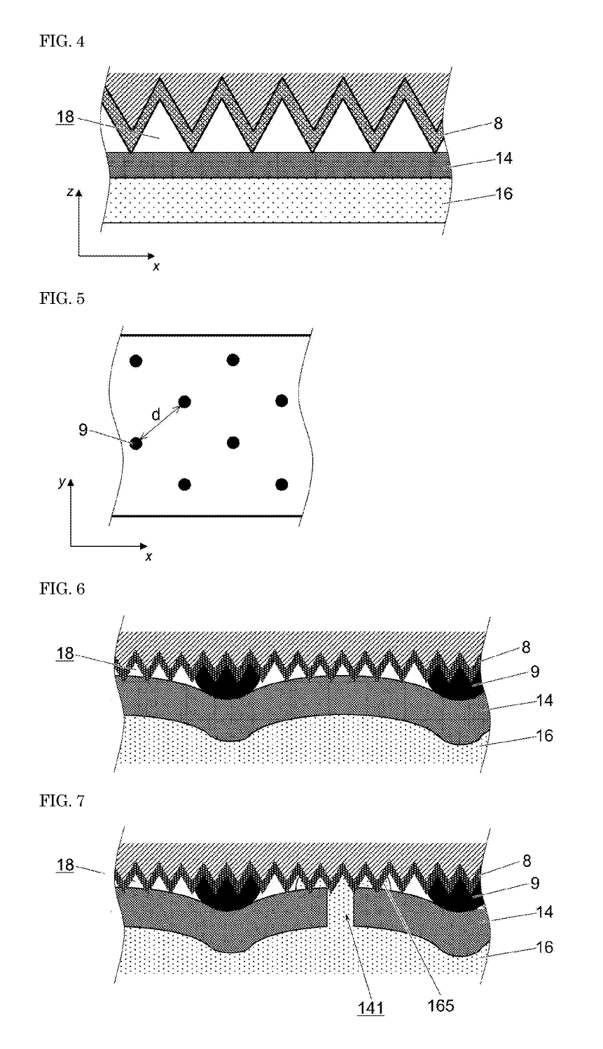

FIG. 6 shows a schematic cross-section of a module including a cell with the buffer electrode 9 provided on the back side transparent electrode layer 8. When the buffer electrode 9 is disposed, the buffer electrode 9 and the metal foil 14 first come into contact with each other in application of a pressure, and the metal foil 14 is pressed onto the back side transparent electrode layer 8 where the buffer electrode 9 does not exist. First the buffer electrode 9 receives a pressure from the metal foil 14, and therefore the contact pressure between the back side transparent electrode layer 8 and the metal foil 14 in the region which is not provided with the buffer electrode 9 is equalized. Thus, local application of a pressure to the back side transparent electrode layer 8 is suppressed, so that mechanical damage can be reduced.

On a surface of the cell on the back side, the area of a region provided with the buffer electrode 9 is preferably less than 1% of the area of a region in which the back side transparent electrode layer 8 is exposed. Thus, the ratio A2/A1 is preferably less than 0.01 where A1 is the area of a region in which the back side transparent electrode layer 8 is exposed, and A2 is the total area of dot-shaped buffer electrodes. The ratio A2/A1 is more preferably 0.002 to 0.007. When the buffer electrode-formed area is within the above-mentioned range, low contact resistance and moderate pressure dispersion can be expected. As compared to a case where a grid shape metal electrode is formed, the use amount of electrode materials such as an Ag paste is smaller, and therefore the production cost can be reduced.

The height of the buffer electrode is preferably larger than the height of irregularities on the back surface of the cell. The height of the buffer electrode is preferably about 6 to 30 μm. The height of the buffer electrode 9 is more preferably about 10 to 25 μm from the viewpoint of a balance between reduction of the material cost and the buffering ability. The diameter of the buffer electrode is preferably about 10 to 100 μm, and more preferably about 30 to 60 μm from the viewpoint of utilization efficiency of materials and uniformity of patterning. The distance d between buffer electrodes closest to each other is preferably about 0.5 to 3 mm. When the size of the buffer electrode and the distance between the buffer electrodes are within the above-mentioned ranges, respectively, mechanical damage tends to be reduced, leading to suppression of a reduction in open circuit voltage (Voc) which is associated with modularization. Due to equalization of the pressure, contact resistance is equalized, series resistance decreases, and the fill factor (FF) of the module tends to be improved.

As a material of the buffer electrode, for example, a paste obtained by mixing fine particles formed of a material such as Sn, Ag, Ni, Al, Cu or carbon and a binder such as epoxy or PVDF can be used, and it is preferable to use fine particles formed of at least one of Sn, Ag and Ni from the viewpoint of pressure relaxation and contact resistance. The buffer electrodes can be formed by, for example, screen printing.

The metal foil 14 may be provided with an opening. When the metal foil 14 is provided with an opening 141 as shown in FIG. 7, the back side encapsulant 16 flows to the back surface of the cell 13 through the opening 141, and therefore adhesion can be improved. An encapsulant 165 may flow into gaps between the metal foil 14 and the back side transparent electrode layer 8 (or buffer electrode 9) as the encapsulant 16 flows not only to just above the opening 141 but also to the periphery of the opening 141.

The diameter of the opening 141 of the metal foil 14 is preferably 100 to 2000 μm, more preferably 200 to 1500 μm, further preferably 400 to 900 μm. When the diameter of the opening is 100 μm or more, the encapsulant 16 can easily pass through the opening, so that adhesion with the cell is improved. When the diameter of the opening is 2000 μm or less, the encapsulant 16 is prevented from excessively flowing into gaps between the metal foil 14 and the cell 13, so that the contact area between the metal foil and the back surface of the cell can be maintained.

The distance between openings closest to each other is preferably 5 to 100 mm, more preferably 6 to 26 mm. When the distance between the openings is within the above-mentioned range, the contact area between the metal foil 14 and the back side transparent electrode layer 8 and buffer electrode 9 can be secured while adhesion between the encapsulant 16 and the cell 13 on the back side is kept appropriately.

As described above, the metal foil 14 disposed in contact with the back surface of the cell 13 serves as a metal electrode that feeds a current in the in-plane direction of the back surface of the solar cell. The metal foil 14 can be used for interconnection between adjacent cells.

In the module shown in FIG. 1, the connection member (interconnector) 12 such as a tab line is mounted on the light-receiving side metal electrode 1. The light-receiving side metal electrode 1 and the connection member 12 can be electrically connected through solder, a conductive adhesive, a conductive film or the like. One end of the connection member 12 mounted on the light-receiving side metal electrode is mounted on the metal foil 14 disposed in contact with the adjacent cell.

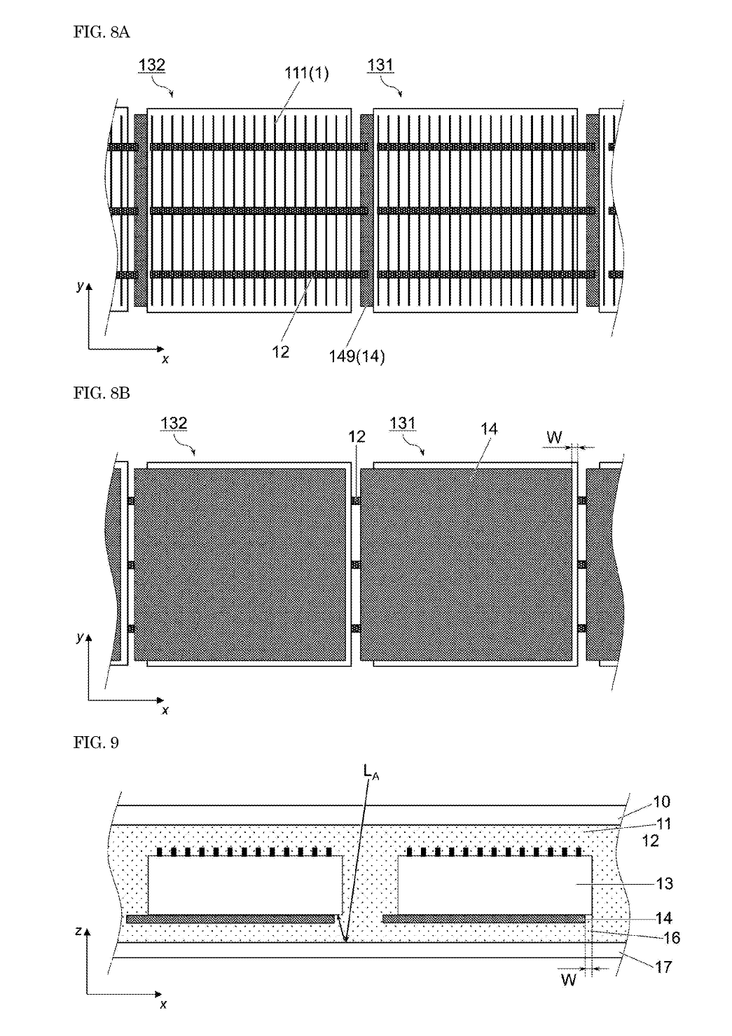

FIG. 8A is a plan view of a light-receiving surface of a solar cell module in which the connection member 12 mounted on the light-receiving side metal electrode 1 is connected to a projected portion 149 of the metal foil 14 disposed in contact with the adjacent cell. FIG. 8B is a plan view of a back surface of the module.

Cells 131 and 132 included in this module each have a rectangular shape or a substantially rectangular shape in a plan view. The substantially rectangular shape is a shape of a rectangle, the corners of which are chamfered. The substantially rectangular shape is also referred to as a semi-square shape. The metal foil 14 that is in contact with the back surface of one cell 131, of two adjacent cells 131 and 132, is disposed so as to have the projected portion 149 in which the metal foil protrudes to the other cell 132 side. When the connection member 12 connected to the light-receiving surface of the cell 132 is connected to the projected portion 149 of the metal foil 14 that is in contact with the back surface of the cell 131, the two cells are electrically connected.

When an interconnector composed of a metal having a thermal expansion coefficient different from that of the silicon substrate is fixed to the cell with solder, an adhesive or the like interposed therebetween, stress is generated at the bonding interface due to a temperature change etc. When an interconnector is mounted on each of both surfaces of the cell, there is a difference between the magnitudes and directions of stress on the front side and on the back side, so that strain may be easily generated, leading to reduction of Voc due to strain, peeling of the interconnector, cell breakage due to stress, and so on.

On the other hand, in the embodiment shown in FIGS. 8A and 8B, only the metal foil 14 is in contact with the back side of the cell in a non-bonded state, and a bonding member is not used. Thus, deterioration of module characteristics due to a temperature change hardly occurs, so that excellent reliability is exhibited. Since it is not necessary to connect an interconnector to the back surface of the cell, cell interconnection operation can be simplified to improve productivity of the module.

It is preferable that on three sides other than a side on which the projected portion 149 of the metal foil exists, among the four sides of the rectangular or substantially rectangular cell, the metal foil 14 is disposed inside the peripheral edge of the cell, and the cell is exposed at an end portion which is not covered with the metal foil. Thus, it is preferable that the peripheral edge of the metal foil exists inside the peripheral edge of the cell except for the projected portion 149 for establishing connection to the adjacent cell.

When an exposed portion which is not provided with the metal foil 14 exists on the peripheral portion of the back surface of the cell, light LA incident to a gap between adjacent cells followed by reflection at the back sheet 17 can be caused to pass into the cell from the exposed portion of the back surface of the cell as schematically shown in FIG. 9, so that light utilization efficiency of the module is improved. The width W of the exposed portion of the back surface of the cell is preferably about 0.3 to 2 mm, more preferably about 0.5 to 1.5 mm.

A plurality of cells are interconnected to form a solar cell string, encapsulation is performed with an encapsulant disposed on each of both surfaces of the solar cell string, whereby the cells are modularized. In interconnection, alignment of each cell and metal foil is performed, and relative alignment of a plurality of cells is performed.

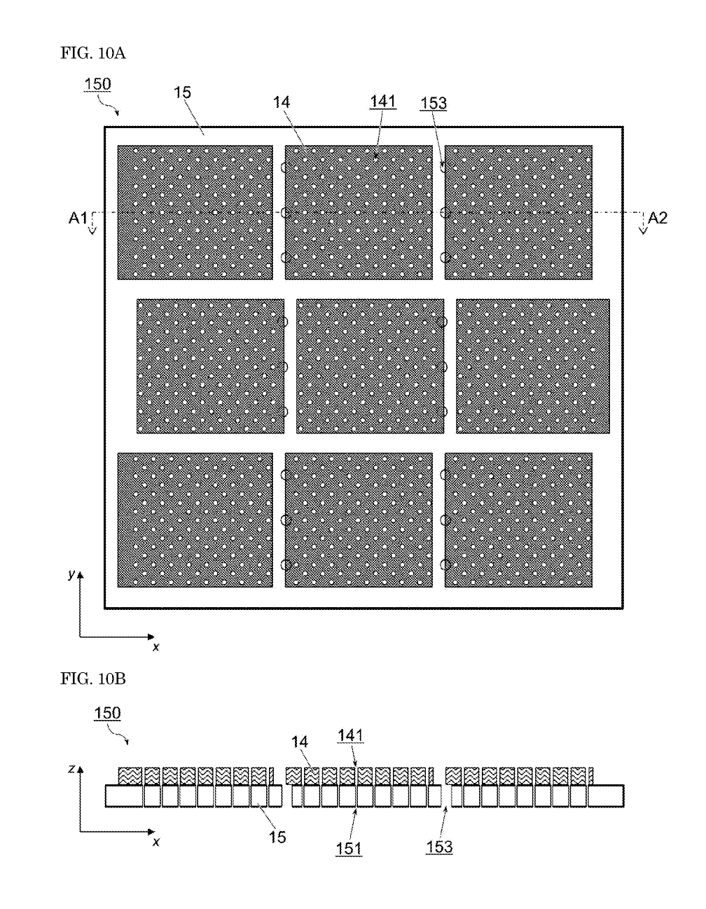

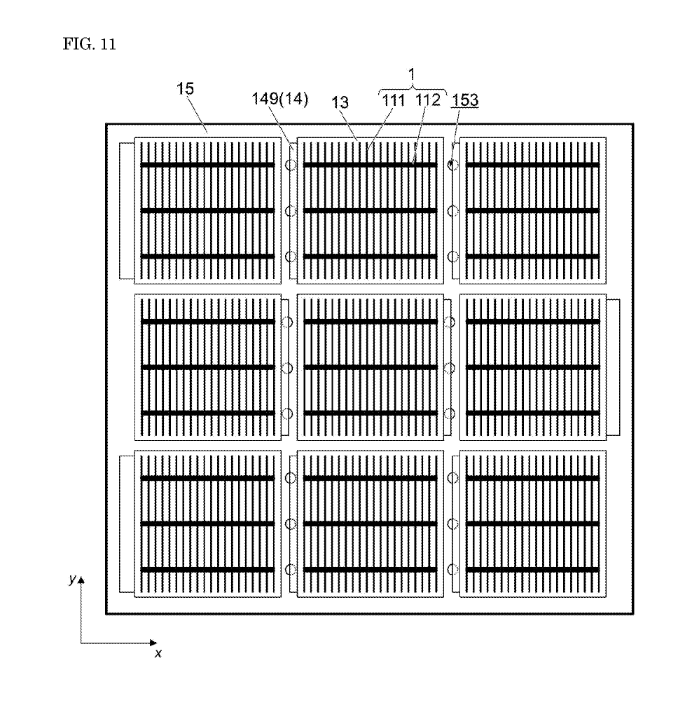

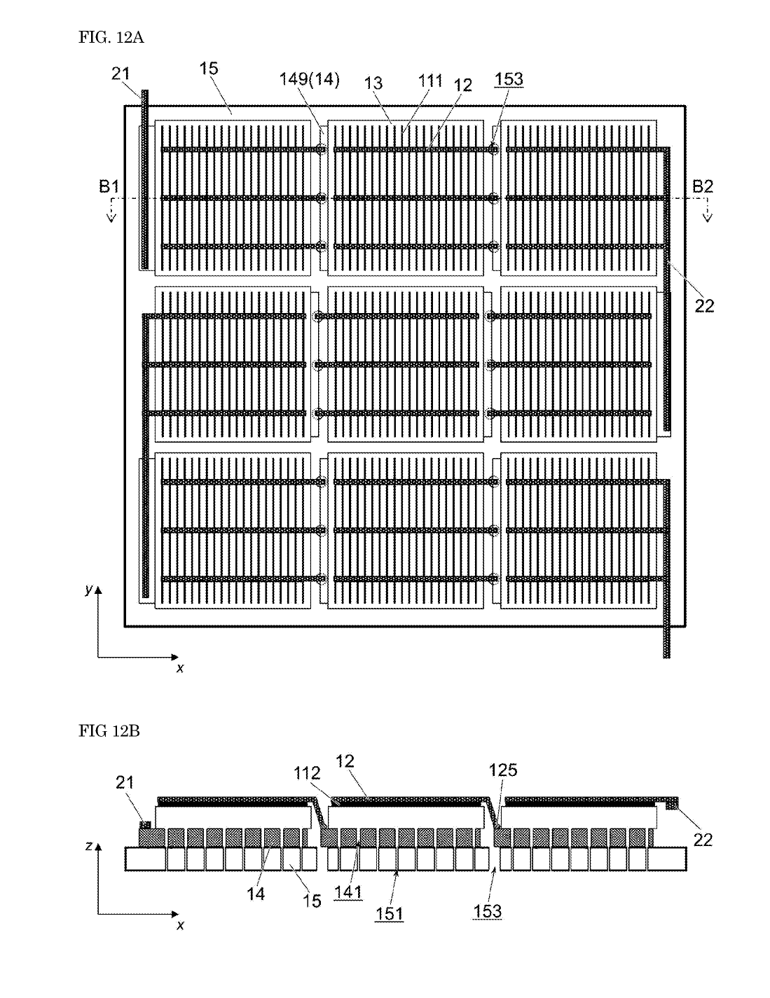

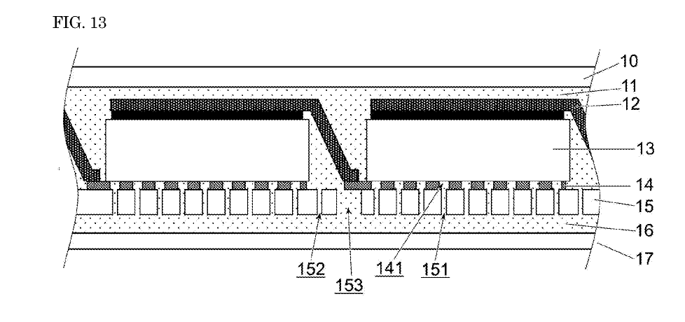

By using a wiring sheet 150 with a plurality of metal foils fixed on an insulating support, alignment operation can be simplified. FIG. 10A is a plan view of the wiring sheet 150 with the metal foil 14 fixed on a sheet-shaped insulating member 15, and FIG. 10B is a sectional view taken along line A1-A2. FIG. 11 is a plan view showing a state in which a cell is placed on a surface of a metal foil on a side opposite to a surface fixed with an insulating member, the metal foil being fixed to a wiring sheet. FIG. 12A is a plan view showing a state in which light-receiving side metal electrodes (bus bar electrodes) and metal foils in two adjacent cells are interconnected by the connection member 12. FIG. 12B is a sectional view taken along line B1-B2. FIG. 13 is a schematic sectional view of a module in which cells are interconnected using a wiring sheet.

The material and the thickness of the insulating member 15 are not particularly limited as long as it is capable of supporting the metal foil, and has heat resistance at a lamination temperature (e.g., 120 to 150° C.) in encapsulation. The insulating member 15 may have any of light-transmissivity, light-absorbency and light-reflectivity. When a light-reflective back sheet is used, it is preferable that the insulating member 15 has light-transmissivity. As the insulating member 15, a PET (polyethylene terephthalate) resin sheet is preferably used from the viewpoint of transparency and the material cost.

A plurality of metal foils 14 matching the number of cells included in one module are fixed on the insulating member 15. For example, in FIG. 10A, nine (3×3) metal foils 14 are disposed separately from one another on one insulating member 15. The method for fixing the insulating member 15 and the metal foil 14 to each other is not particularly limited, and the metal foil can be fixed by, for example, static electricity, an adhesive, welding or the like. Particularly, it is preferable that the metal foil is fixed on the insulating member by a low-adhesion pressure sensitive adhesive.

When the metal foil 14 is provided with a plurality of openings 141 as shown in FIG. 10A, it is preferable that the insulating member 15 has first-kind opening sections 151 at positions corresponding to the openings of the metal foil. The “position corresponding to the opening of the metal foil” means a position at which the opening is provided in the metal foil that is in contact with the back surface of the cell. In the module after encapsulation, the back sheet 17, the back side encapsulant 16, the insulating member 15, the metal foil 14 and the cell 13 are disposed in this order from the back side as shown in FIG. 13. When first-kind opening sections 151 of the insulating member 15 are provided at positions corresponding to openings 141 of the metal foil 14, the back side encapsulant 16 flows to the back surface of the cell 13 through first-kind opening sections 151 of the insulating member 15 and openings 141 of the metal foil 14, and therefore adhesion can be improved.

The diameter of the first-kind opening section 151 provided in the insulating member 15 is preferably smaller than the diameter of the opening 141 of the metal foil 14. When the opening of the metal foil is larger than the opening section of the insulating member, the pressure of inflow of the encapsulant is relaxed at the opening of the metal foil. Thus, the encapsulant 16 is inhibited from excessively flowing into gaps between the metal foil 14 and the cell 13, so that the contact area between the metal foil and the back surface of the cell can be maintained. In a region where openings are provided in the metal foil, and first-kind opening sections are not provided in the insulating member, the back surface of the cell 13 and the insulating member 15 are bonded to each other with the encapsulant 16 interposed therebetween. Accordingly, the metal foil 14 is sandwiched and fixed between the insulating member and the cell, so that the cell 13 and the metal foil 14 can be brought into contact with each other more reliably. The diameter of the first-kind opening section 151 of the insulating member 15 is more preferably about 30 to 80%, further preferably 30 to 60%, of the diameter of the opening 141 of the metal foil 14. The diameter of the first-kind opening section 151 is preferably 270 to 1000 μm, more preferably 300 to 700 μm.

Preferably, the insulating member 15 has second-kind opening sections in regions where the metal foil 14 is not disposed, i.e., second-kind opening sections 152 at positions corresponding to gaps between adjacent cells (see FIG. 13). Since opening sections are provided at positions corresponding to gaps between adjacent cells, the encapsulant easily flows not only to the back surface of the cell, but also to the lateral surface of the cell and a gap between cells, so that encapsulation can be more reliably performed. The diameter of the second-kind opening section 152 of the insulating member 15 provided in a region where the metal foil is not disposed is preferably 270 to 1000 μm, more preferably 300 to 700 μm.

As shown in FIG. 11, cells are disposed on metal foils 14 on a wiring sheet. By this operation, alignment of the cell 13 and the metal foil 14, and relative alignment of a plurality of cells are performed simultaneously. Thus, alignment operation can be simplified to improve productivity of the module.

In FIG. 11, the cell is not disposed on the metal foil 14 at a portion in which the cell is interconnected to the adjacent cell. Thus, the cell 13 is disposed in such a manner that the metal foil 14 has the projected portion 149 protruding from the cell-disposed region.

The connection member 12 is mounted on the light-receiving side metal electrode 1 of the cell 13 and the projected portion 149 of the metal foil 14 to form a solar cell string in which a plurality of cells are connected in series as shown in FIGS. 12A and 12B. In FIG. 12A, three solar cell strings each having three cells connected in the x direction are arranged in the y direction, and adjacent solar cell strings are connected by a lead wire 22. To a cell at an end portion is connected a lead wire 21 for extracting a current to outside.

As shown in FIG. 12B, the connection member 12 is mounted on the bus bar electrode 112 of the light-receiving surface. As described above, the connection member 12 and the bus bar electrode 112 (light-receiving side metal electrode) can be electrically connected using solder, a conductive adhesive, a conductive film or the like. For electrical connection of the connection member 12 and the bus bar electrode 112, solder, a conductive adhesive, a conductive film or the like can be used. For facilitating connection operation, it is preferable to connect the metal foil and the connection member by a method to identical to the method for connecting the light-receiving side metal electrode and the connection member. For example, when the light-receiving side metal electrode 1 and the connection member 12 are soldered to each other, it is preferable to connect the metal foil 14 and the connection member 12 by soldering. In FIG. 12B, a solder-welded portion 125 is formed at a connection portion (interconnection portion) with the connection member on the metal foil 14.

When interconnection is performed with the connection member 12 mounted onto the metal foil 14 by soldering etc., the insulating member may be melted or deformed by heating. Particularly, when a resin film of PET or the like is used as an insulating member, the insulating member is easily melted or deformed because the heating temperature during interconnection exceeds the heat-resistant temperature of the insulating member. For preventing a failure caused by heat during interconnection, it is preferable that in the insulating member 15, third-kind opening sections 153 are provided in regions including positions corresponding to interconnection portions, i.e., at positions corresponding to portions where the metal foil 14 and the connection member 12 overlap each other, and on the periphery thereof.

When third-kind opening sections 153 are provided at interconnection portions and on the periphery thereof, melding or deformation of the insulating member due to elevation of the temperature of the insulating member during interconnection can be prevented. When the insulating member 15 is provided with third-kind opening sections, soldering or the like can be performed by heating from the back side through the third-kind opening sections. When opening sections 153 are provided, it is easy to re-solder a connection failure portion even if the connection failure portion is generated in interconnection by heating from the light-receiving side.

The size of the third-kind opening section of the insulating member is not particularly limited, but the opening is preferably larger than the interconnection portion. Preferably, the third-kind opening section 153 is provided so as to extend over a region in which the metal foil 14 is disposed and a region in which the metal foil is not disposed. Although circular third-kind opening sections are shown in FIGS. 10 to 12, the shape of the third-kind opening section is not limited to a circular shape. For example, the third-kind opening section may be provided so as to extend in a direction (y direction) orthogonal to the interconnection direction along the end portion of a region provided with the metal foil (projected portion of the metal foil).

After a plurality of cells are connected on a wiring sheet to form a solar cell string, an encapsulant and a protecting member are disposed and stacked on the light-receiving side and the back side, respectively, of the solar cell string, and heated and press-bonded, whereby the encapsulant flows between cells and to the edges of the module to perform encapsulation. When the insulating member 15 and the metal foil 14 are provided with openings, the encapsulant flows to the back surface of the cell 13 through the opening as shown in FIG. 12. Thus, the cell and the encapsulant come into close contact with each other to suppress ingress of moisture etc. Thus, a solar cell module having high reliability is obtained.

### EXAMPLES

Hereinafter, the present invention will be described in detail by showing examples, but the present invention is not limited to the following examples.

[Preparation of Heterojunction Solar Cell]

A 200 μm-thick 6 inch n-type single-crystalline silicon substrate having an incident surface with a (100) plane orientation was washed in acetone, immersed in a 2 wt % HF aqueous solution for 5 minutes to remove a silicon oxide layer on a surface, and rinsed twice with ultra-pure water. Thus obtained substrate was immersed for 15 minutes in a 5/15 wt % KOH/isopropyl alcohol aqueous solution held at 75° C. Thereafter, the substrate was immersed in a 2 wt % HF aqueous solution for 5 minutes, rinsed twice with ultra-pure water, and dried at normal temperature. The surfaces of the single-crystalline silicon substrate were observed with an atomic force microscope (AFM). Quadrangular pyramid-like textured structures were formed on both surfaces and the arithmetic mean roughness thereof was 2100 nm.

The texture-formed single-crystalline silicon substrate was introduced into a CVD apparatus, and a 4 nm-thick i-type amorphous silicon layer was formed as a light-receiving side intrinsic silicon layer on the light-receiving surface. On the i-type amorphous silicon layer, a 5 nm-thick p-type amorphous silicon layer was formed as a light-receiving side conductive silicon layer. Deposition conditions of the light-receiving side intrinsic silicon layer were the followings: the substrate temperature was 180° C.; the pressure was 130 Pa; the SiH₄/H₂ flow rate ratio was 2/10; and the input power density was 0.03 W/cm². Deposition conditions of p-type amorphous silicon layer were the followings: the substrate temperature was 190° C.; the pressure was 130 Pa; the SiH₄/H₂/B₂H₆ flow ratio was 1/10/3; and the input power density was 0.04 W/cm². As the B₂H₆ gas mentioned above, a gas diluted with H₂ to a B₂H₆ concentration of 5000 ppm was used.

The substrate was transferred to a sputtering chamber without being exposed to air. On the p-type amorphous silicon layer, a 120 nm-thick ITO layer was formed as a light-receiving side transparent electrode. As a sputtering target, one obtained by adding 10% by weight of SnO₂ to In₂O₃ was used.

The substrate with the ITO layer deposited on the light-receiving surface was reversed, and introduced into a CVD apparatus, and a 5 nm-thick i-type amorphous silicon layer was deposited on the back surface of the silicon substrate as a back side intrinsic silicon layer. A 10 nm-thick n-type amorphous silicon layer was deposited thereon as a back side conductive silicon layer. Deposition conditions of the n-type amorphous silicon layer were the followings: the substrate temperature was 180° C., the pressure was 60 Pa, the SiH₄/PH₃ flow rate ratio was 1/2, and the input power density was 0.02 W/cm². As the PH₃ gas, a gas diluted with H₂ to a PH₃ concentration of 5000 ppm was used.

Next, the substrate was transferred to a sputtering chamber without being exposed to atmospheric air, and a 100 nm-thick ITO layer was deposited on the n-type amorphous silicon layer as a back side transparent electrode layer.

In the following examples and comparative examples, a solar cell was prepared using the solar cell in process, which was obtained as described above, and a plurality of solar cells were connected through an interconnector to modularize the solar cells.

### Example 1

(Formation of Metal Electrode)

On an ITO layer on a light-receiving surface, a silver paste was screen-printed to form a grid shape light-receiving side metal electrode including finger electrodes and bus bar electrodes as shown in FIG. 3B. A metal electrode was not disposed on an ITO layer on a back surface, and a solar cell was formed in such a manner that a back side transparent electrode layer is an outermost surface layer.

(Interconnection)

A metal foil (36 μm-thick copper foil) was cut into a rectangular shape, and brought into contact with the ITO layer on the back surface of the solar cell. The metal foil was disposed in such a manner that a projected portion exposed outside the end portion of a cell existed on a side where the cell was interconnected to the adjacent cell, and an end portion of the metal was situated 0.5 mm inside the end portion of the solar cell on the other three sides.

For interconnection of adjacent cells, a connection member obtained by covering a 1.5 mm-wide and 200 μm-thick strip-shaped copper foil with solder was used. Three connection members disposed at equal intervals were abutted against bus bar electrodes on the light-receiving surface and the projected portion of the metal foil disposed in contact with the back surface of the adjacent cell, and a soldering iron heated to 360° C. was pressed thereto, whereby adjacent cells were electrically connected to form a solar cell string with nine solar cells connected in series. Six solar cell strings (54 solar cells in total) were connected in series to prepare a string assembly.

(Encapsulation)

A 4 mm-thick white glass plate as a light-receiving surface protecting member, a 400 μm-thick EVA sheet as each of a light-receiving side encapsulant and a back side encapsulant, and a PET film as a back sheet were provided, the string assembly was sandwiched between the two EVA sheets, and lamination was performed at 150° C. for 20 minutes to obtain a solar cell module.

### Example 2

(Formation of Metal Electrode)

In the same manner as in Example 1, a grid shape metal electrode was formed on an ITO layer on a light-receiving surface. Further, dot-shaped metal electrodes (buffer electrodes) each having a diameter of 30 to 70 μm were formed on an ITO layer on a back surface by screen printing. The dot-shaped metal electrodes were disposed at intervals of 1 mm in a triangular grid shape.

(Interconnection and Encapsulation)

In the same manner as in Example 1, a metal foil was disposed on the back surface of each of solar cells, the solar cells were interconnected to prepare a string assembly, and encapsulation was performed. A cross-section of the module after encapsulation was examined, and the result showed that the metal foil was deformed in the disposition cycle of buffer electrodes. In a region within 200 μm to 300 μm from the periphery of the buffer electrode, the metal foil was not in contact with a back side transparent electrode layer, and in a region more distant from the periphery of the buffer electrode, the metal foil was in physical contact with the back side transparent electrode layer.

### Example 3

A wiring sheet obtained by arranging 54 (9×6) metal foils on a PET film and bonding the metal foils to the PET film was used. In the PET film and the metal foils of the wiring sheet, openings were provided at intervals of 25 mm in a square grid shape in regions where the PET film and the metal foil overlapped each other. The diameter of each of the openings provided in the PET film and the metal foil was 300 μm A cell with dot-shaped buffer electrodes provided on the back surface in the same manner as in Example 2 was disposed on the wiring sheet, and a connection member was soldered to bus bar electrodes on the light-receiving surface and projected portions of the metal foils to perform interconnection.

### Example 4

A wiring sheet with metal foils having openings each having a diameter of 800 μm was used. A solar cell module was prepared in the same manner as in Example 3 except for the above.

### Example 5

In Example 5, a PET film of a wiring member had opening sections not only in regions where the metal foil was disposed, but also at connection portions (interconnection portions) between a connection member and the metal foil, and in regions of gaps between cells where the metal foil was not provided. The opening sections at the interconnection portion were provided so as to surround the interconnection portion, and openings reached outside the end portion of a region where the metal foil was disposed. Interconnection was performed by soldering a connection member to the metal foil disposed on the opening sections (see FIG. 13). A solar cell module was prepared in the same manner as in Example 4 except for the above.

### Example 6

A metal foil cut to a size larger than that in Example 1. The metal foil was disposed so as to protrude about 0.5 mm outside the end portion of the cell on three sides other than a side involved in interconnection to the adjacent cell. A solar cell module was prepared in the same manner as in Example 1 except for the above.

### Comparative Example 1

In the same manner as in Example 1, a grid shape metal electrode was formed on an ITO layer on a light-receiving surface. Further, a grid shape metal electrode was formed on an ITO layer on a back surface. The number of bus bar electrodes on the back side was 3 and equal to the number of bus bar electrodes on the light-receiving side, and the number of finger electrodes on the back side was three times as large as the number of finger electrodes on the light-receiving side. The metal foil was disposed in contact with the back surface of a solar cell, and the bus bar electrodes of a back side grid electrode and a metal foil were bonded using a conductive adhesive, and fixed together. A solar cell module was prepared in the same manner as in Example 1 except for the above.

### Comparative Example 2

In the same manner as in Comparative Example 1, a grid shape metal electrode was formed on each of both a light-receiving surface and a back surface. Bus bar electrodes on the back surface and a metal foil were bonded using an epoxy-based insulating adhesive in place of the conductive adhesive in Comparative Example 1. The whole surface of the metal foil at portions other than projected portions was coated with the epoxy-based adhesive, and press-bonded to the back surface of the solar cell in a heated state at about 150 to 160° C. to bond metal electrodes to the metal foil. In this example, metal electrodes (bus bar electrodes and finger electrodes) having a projected structure with respect to a back side transparent electrode layer break through an epoxy resin layer in press-bonding, and the epoxy resin is cured with the metal electrodes being in contact with the metal foil, so that the metal electrodes are bonded to the metal foil in a contact state.

### Comparative Example 3

In the same manner as in Comparative Example 1, a grid shape metal electrode was formed on each of both a light-receiving surface and a back surface. Bus bars on the light-receiving surface and bus bars on the back surface of the adjacent cell were soldered and connected to a connection member to electrically connect adjacent cells without using a metal foil. A solar cell module was prepared in the same manner as in Comparative Example 1 except for the above.

### Comparative Example 4

Except that a back side transparent electrode layer was bonded to a metal foil with a conductive adhesive, the same procedure as in Example 1 was carried out to prepare a solar cell module.

### Comparative Example 5

As in Example 2, dot-shaped buffer electrodes were formed on a back side transparent electrode layer, and except that the back side transparent electrode layer and buffer electrodes were bonded to a metal foil with a conductive adhesive, the same procedure as in Example 2 was carried out to prepare a solar cell module.

[Evaluation]

The initial power generation characteristics of the solar cell module in each of Examples and Comparative Examples were measured, and a temperature cycle test was then conducted in accordance with JIS C8917. The solar cell module was introduced into a test bath, and then subjected to a temperature cycle test including 200 cycles. Each cycle includes a process in which the solar cell module is held at 85° C. for 10 minutes, cooled to −40° C. at a rate of 80° C./minute, held at −40° C. for 10 minutes, and heated to 85° C. at a rate of 80° C./minute. The power generation of the solar cell module after the temperature cycle test was measured, and the ratio of the power after the temperature cycle test to the initial power (retention) in the solar cell module was determined. The configuration of the solar cell module, the initial power generation characteristics, and the retention after the temperature cycle test are shown in Table 1.

TABLE 1

| | | Metal foil | | | | | | | | | |
|---|---|---|---|---|---|---|---|---|---|---|---|
| | | | | | Position of end portion | | | | | | |
| | | | | | Inside or | Distance | Insulating member | | | | |
| | Back | | Connection | Diameter | outside of | from | | Diameter | Initial stage | | |
| | side | | to back | of | peripheral | peripheral | | of | Series | | |
| | metal | Presence/ | surface | opening | edge | edge of cell | Presence/ | opening | resistance | Power | |
| | electrode | absence | of cell | (μm) | of cell | (mm) | absence | (μm) | (Ω) | (W) | Retention |
| Example 1 | None | Present | Non-bonded | — | Inside | 0.5 | — | — | 0.346 | 273.2 | 96.30% |
| | | | contact | | | | | | | | |
| Example 2 | Dot | Present | Non-bonded | — | Inside | 0.5 | — | — | 0.313 | 274.5 | 96.89% |
| | | | contact | | | | | | | | |
| Example 3 | Dot | Present | Non-bonded | 300 | Inside | 0.5 | Present | 300 | 0.330 | 274.2 | 97.52% |
| | | | contact | | | | | | | | |
| Example 4 | Dot | Present | Non-bonded | 800 | Inside | 0.5 | Present | 300 | 0.325 | 274.3 | 97.91% |
| | | | contact | | | | | | | | |
| Example 5 | Dot | Present | Non-bonded | 800 | Inside | 0.5 | Present | 300 | 0.322 | 274.9 | 98.02% |
| | | | contact | | | | | | | | |
| Example 6 | None | Present | Non-bonded | — | Outside | 0.5 | — | — | 0.342 | 272.5 | 96.40% |
| | | | contact | | | | | | | | |
| Comparative | Grid | Present | Conductive | — | Inside | 0.5 | — | — | 0.359 | 269.8 | 93.29% |
| Example 1 | | | adhesive | | | | | | | | |
| Comparative | Grid | Present | Insulating | — | Inside | 0.5 | — | — | 0.464 | 259.8 | 95.47% |
| Example 2 | | | adhesive | | | | | | | | |
| Comparative | Grid | — | Solder- | — | Inside | 0.5 | — | — | 0.357 | 272.8 | 96.25% |
| Example 3 | | | connection | | | | | | | | |
| | | | between bus | | | | | | | | |
| | | | bar and | | | | | | | | |
| | | | connection | | | | | | | | |
| | | | member | | | | | | | | |
| Comparative | None | Present | Conductive | — | Inside | 0.5 | — | — | 0.379 | 269.1 | 93.50% |
| Example 4 | | | adhesive | | | | | | | | |
| Comparative | Dot | Present | Conductive | — | Inside | 0.5 | — | — | 0.358 | 270.3 | 93.80% |
| Example 5 | | | adhesive | | | | | | | | |

Examples 1 to 5 showed a higher initial power and retention after the cycle test as compared to Comparative Example 3 in which metal electrodes on the front and back sides were connected by a connection member without using a metal member. The reason why the initial power was improved in Examples 1 to 5 may be that existence of voids between the metal foil and the back side transparent electrode improved the reflectance, leading to an increase in current. Further, it is considered that the back electrode of the cell and the metal foil were in contact with each other in a non-bonded state, and therefore even when dimensions were changed due to a temperature change, stress was not generated at the interface between the cell and the metal foil, and deterioration of characteristics resulting from stress strain etc. was suppressed, resulting in improvement of the retention after the cycle test.

Comparative Examples 1 and 2 in which the metal foil and the back side grid electrode were bonded using an adhesive had a lower initial power and retention after the temperature cycle test as compared to Comparative Example 3. It is considered that in Comparative Example 1, absorption of light by a conductive adhesive caused reduction of the initial power. In Comparative Example 2, series resistance increased, and the fill factor decreased. This may be because the contact area between the back side grid electrode and the metal foil decreased due to interposition of an insulating adhesive.

In Comparative Examples 1 and 2, series resistance increased after the cycle test although these data are not shown in Table 1. This may be because since a metal foil and a solar cell having mutually different thermal expansion coefficients were bonded by an adhesive, stress at the interface was not relaxed, and thus peeling occurred locally.

Among Examples, Examples 3 to 5 showed a high retention after the cycle test. This may be because through openings provided the metal foil and the insulating member, the encapsulant was bonded to the back side transparent electrode layer to suppress displacement of the metal foil due to thermal expansion during the temperature cycle test.

Particularly, Examples 4 and 5 showed a high retention. This may be related to the fact that the diameter of the opening of the metal foil is larger than the diameter of the opening of the insulating member. When the opening of the metal foil is larger than the opening of the insulating layer, a region having an insulating member under the openings of the metal foil (region where the insulating member is not provided with openings) exists. Thus, an encapsulant can be interposed between the insulating member and the back side metal electrode layer, and the metal foil sandwiched between the insulating member and the back side transparent electrode layer is fixed by the encapsulant, so that displacement is suppressed. This may be one cause of the high retention in Examples 4 and 5. Thus, it is considered that in Examples 4 and 5, the retention after the cycle test was improved because due to interposition of the encapsulant, the cell and the metal foil were in contact with each other in a non-bonded state while the relative positions of the cell and the metal foil were fixed.

Example 6 in which a metal foil larger in size than the cell was used showed a slightly lower initial power as compared to Example 1. This is because of light reflected in the module, light reflected at the back sheet to reach the end portion of the cell was blocked off by the metal foil, so that the light was unable to pass into the cell, and therefore the current value decreased. It is considered that in Examples 1 to 5, since the end portion of the metal foil was situated at the inside of the cell at portions other than projected portions for interconnection, light was efficiently recovered, so that the current value relatively increased, leading to improvement of the power generation.

### DESCRIPTION OF REFERENCE CHARACTERS

1 light-receiving side metal electrode
2 light-receiving side transparent electrode
3 light-receiving side conductive silicon layer
4 light-receiving side intrinsic silicon layer
5 single-crystalline silicon substrate
6 back side intrinsic silicon layer
7 back side conductive silicon layer
8 back side transparent electrode layer
9 buffer electrode
10 light-receiving surface protecting member
11 light-receiving side encapsulant
12 connection member
13 solar cell
14 metal foil
   141 opening
15 insulating member
   151, 152, 153 opening
16 back side encapsulant
17 back sheet

What is claimed is:

1. A solar cell module comprising:
a first solar cell comprising, in the following order, a single-crystalline silicon substrate, a conductive silicon layer, and a back side transparent electrode layer, wherein the conductive silicon layer and the back side transparent electrode layer are disposed on a back side of the single-crystalline silicon substrate;
an encapsulant; and
a flexible metal foil disposed between the back side transparent electrode layer and the encapsulant, wherein
the flexible metal foil is in contact with the back side transparent electrode layer in a non-bonded state, and
the encapsulant encapsulates the first solar cell and maintains a contact state between the flexible metal foil and the back side transparent electrode layer.

2. The solar cell module according to claim 1, wherein at least a part of the flexible metal foil is composed of at least one selected from the group consisting of Sn, Ag, Ni, In, and Cu.

3. The solar cell module according to claim 1, wherein a thickness of the flexible metal foil is 4 to 190 μm.

4. The solar cell module according to claim 1, wherein
a plurality of dot-shaped buffer electrodes are disposed on the back side transparent electrode layer separately from one another, and wherein
the flexible metal foil is in contact with the buffer electrodes in a non-bonded state, and is electrically connected to the back side transparent electrode layer and the buffer electrodes.

5. The solar cell module according to claim 4, wherein on a back surface of the first solar cell, an area of a region occupied by the buffer electrodes is less than 1% of an area of a region in which the back side transparent electrode layer is exposed.

6. The solar cell module according to claim 1, wherein
the flexible metal foil is provided with a plurality of openings, and
the encapsulant is in contact with the first solar cell through the openings.

7. The solar cell module according to claim 6, wherein a diameter of the opening is 100 μm to 2000 μm, and a distance between the openings closest to each other is 5 mm to 100 mm.

8. The solar cell module according to claim 1, wherein the flexible metal foil is fixed on an insulating member, and the back side transparent electrode layer is in contact in a non-bonded state with a surface of the flexible metal foil on a side opposite to a surface fixed with the insulating member.

9. The solar cell module according to claim 8, wherein
the flexible metal foil is provided with a plurality of openings,
the insulating member has first opening sections at positions corresponding to the openings of the flexible metal foil, and
the encapsulant is in contact with a back surface of the first solar cell through the first opening sections provided in the insulating member and the openings provided in the flexible metal foil.

10. The solar cell module according to claim 9, wherein a diameter of the first opening section is smaller than a diameter of the opening provided in the flexible metal foil.

11. The solar cell module according to claim 8, wherein
the insulating member has second opening sections in a region where the flexible metal foil is not disposed, and
the encapsulant is in contact with a lateral surface of the first solar cell through the second opening sections provided in the insulating member.

12. The solar cell module according to claim 1, further comprising a second solar cell adjacent to the first solar cell, wherein
the second solar cell comprises a patterned metal electrode on a light-receiving surface thereof, and
the flexible metal foil that is in contact with the back side transparent electrode in the first solar cell and the metal electrode of the second solar cell are mounted to a connection member to electrically connect the two adjacent solar cells.

13. The solar cell module according to claim 12, wherein
the flexible metal foil that is in contact with the back side transparent electrode of the first solar cell has a projected portion protruding from a peripheral edge of the first solar cell, and
the connection member is mounted on the projected portion of the flexible metal foil.

14. The solar cell module according to claim 13, wherein
the first and second solar cells have a rectangular shape or a substantially rectangular shape in a plan view,
the projected portion of the flexible metal foil is arranged on a side of the first solar cell which is adjacent to the second solar cell, and
the flexible metal foil is disposed inside three peripheral edges of the first solar cell.

15. The solar cell module according to claim 13, wherein
the flexible metal foil is fixed on an insulating member, and the back side transparent electrode layer is in contact in a non-bonded state with a surface of the flexible metal foil on a side opposite to a surface fixed with the insulating member, and
the insulating member has third opening sections in a region including positions corresponding to connection portions between the projected portion of the flexible metal foil and the connection member.
